(19) United States
(12) Patent Application Publication
(10) Pub. No.: US 2024/0280641 A1
(43) Pub. Date: Aug. 22, 2024

(54) APPARATUS AND METHOD FOR ESTIMATING STATE OF CHARGE OF BATTERY

(71) Applicants: HYUNDAI MOTOR COMPANY, Seoul (KR); KIA CORPORATION, Seoul (KR); The Industry & Academic Cooperation in Chungnam National University (IAC), Daejeon (KR)

(72) Inventors: Ju Seok Kim, Suwon-si (KR); Jong Hoon Kim, Daejeon (KR); Jin Hyeong Park, Yeongdong-gun (KR)

(73) Assignees: HYUNDAI MOTOR COMPANY, Seoul (KR); KIA CORPORATION, Seoul (KR); The Industry & Academic Cooperation in Chungnam National University (IAC), Daejeon (KR)

(21) Appl. No.: 18/223,188

(22) Filed: Jul. 18, 2023

(30) Foreign Application Priority Data
Feb. 16, 2023 (KR) 10-2023-0020534

(51) Int. Cl. G01R 31/3842; G01R 31/367

(52) U.S. Cl. CPC G01R 31/3842; G01R 31/367

(57) ABSTRACT

A method of estimating an SOC value of a battery, includes measuring an initial voltage and an initial current of the battery, estimating resistance parameters of respective battery models based on the measured initial voltage and the measured initial current, converting the estimated resistance parameters by comparing an actually measured voltage value with OCVs determined through the estimated resistance parameters, determining probabilities that the battery corresponds to the respective battery models based on difference values between voltage values of the battery models estimated based on the estimated resistance parameters of the respective battery models and the actually measured voltage value, determining a fused OCV by applying weights to the probabilities that the battery corresponds to the respective battery models based on model OCV information of the respective battery models determined based on the converted resistance parameters, and estimating the SOC value of the battery based on the fused OCV.

### CROSS-REFERENCE TO RELATED APPLICATION

The present application claims priority to Korean Patent Application No. 10-2023-0020534 filed on Feb. 16, 2023, the entire contents of which is incorporated herein for all purposes by this reference.

### BACKGROUND OF THE PRESENT DISCLOSURE

### Field of the Present Disclosure

The present disclosure relates to an apparatus and method for estimating a state of charge (SOC) value of a battery. More particularly, the present disclosure relates to an apparatus and method for estimating an SOC value of a battery in which the SOC value of the battery is estimated through calculation of an open-circuit voltage (OCV) of the battery.

### Description of Related Art

Recently, the eco-friendly vehicle market including hybrid electric vehicles (HEVs), fuel cell electric vehicles (FCEVs), etc. is on a significant growth trend.

Furthermore, as research and development to improve batteries for eco-friendly vehicles and the performance and efficiency of the batteries on vehicle design are continuously performed, the center of the market is expected to shift to pure electric vehicles using only batteries as a power source.

A plurality of batteries may be connected in series and in parallel to achieve high capacity and high output. In the case that a plurality of batteries connected in series and in parallel is alternately charged and discharged, it is necessary to manage the batteries to maintain a proper operating state and performance by controlling charging and discharging of the batteries.

For the present purpose, a battery management system (BMS) is provided to maintain the state and performance of a battery, and the BMS measures the current, voltage, temperature, etc. of the battery, estimates the state of charge (SOC) value of the battery based on the measured data, and controls the SOC value of the battery to maintain the state and performance of the battery.

The BMS may manage the SOC value, state of health (SOH), maximum input and output power allowance, output voltage, etc. of the battery using the state information of the battery, and technology for estimating the replacement time of the battery by predicting the lifespan of the battery becomes a key in more stable system operation.

Conventionally, to predict the lifespan of a battery, the SOH of the battery is estimated using current integration and the rate of SOC change of the battery. When the SOC change of the battery is calculated, there is a possibility that errors of initial and final estimated SOC values of the battery occur depending on battery operating environments and the number of frequencies of charging and discharging of the battery, and thereby, accuracy in estimation of the SOH of the battery may be lowered.

Furthermore, it is difficult to prepare SOC-OCV data corresponding to various battery types through a mode battery performance test, and thus, when the type of an applied battery is not specified, there is a problem that SOC-OCV data does not exist, and thus a separate test needs to be performed to estimate the SOC value of the battery.

The information included in this Background of the present disclosure is only for enhancement of understanding of the general background of the present disclosure and may not be taken as an acknowledgement or any form of suggestion that this information forms the prior art already known to a person skilled in the art.

### BRIEF SUMMARY

Various aspects of the present disclosure are directed to providing an apparatus and method for estimating an SOC value of a battery mounted as a driving unit, in which a plurality of battery models may be stored in a battery management system and an OCV of the battery may be estimated to determine the characteristics of the battery.

Various aspects of the present disclosure are directed to providing an apparatus and method for estimating an SOC value of a battery mounted as a driving unit in which probabilities that the battery corresponds to respective battery models are determined through the information of the battery models stored in a battery management system, and a fused OCV is estimated based on the determined probabilities of the battery depending on the respective battery models.

It is yet another object of the present disclosure to provide an apparatus and method for estimating an SOC value of a battery in which the SOC value of the battery is estimated based on a fused OCV determined depending on battery models.

Various aspects of the present disclosure are directed to providing a method of estimating a state of charge (SOC) value of a battery, including measuring an initial voltage and an initial current of the battery, estimating resistance parameters of respective battery models based on the measured initial voltage and the measured initial current, converting the estimated resistance parameters by comparing an actually measured voltage value with OCVs determined through the estimated resistance parameters, determining probabilities that the battery corresponds to the respective battery models based on difference values between voltage values of the battery models estimated based on the estimated resistance parameters of the respective battery models and the actually measured voltage value, determining a fused OCV by applying weights for the respective battery models to the determined probabilities that the battery corresponds to the respective battery models based on model OCV information of the respective battery models determined based on the converted resistance parameters, and estimating the SOC value of the battery based on the fused OCV.

In an exemplary embodiment of the present disclosure, converting the estimated resistance parameters may include converting the estimated resistance parameters based on difference values between the OCVs determined through the estimated resistance parameters of the respective battery models and the actually measured voltage value, and determining OCVs of the respective battery models based on the converted resistance parameters.

In another exemplary embodiment of the present disclosure, converting the estimated resistance parameters based on the difference values between the OCVs determined through the estimated resistance parameters of the respective battery models and the actually measured voltage value may include converting the estimated resistance parameters by determining error covariances and applying weights to the difference values between the OCVs through the estimated resistance parameters of the respective battery models determined and the actually measured voltage value.

In yet another exemplary embodiment of the present disclosure, determining the probabilities that the battery corresponds to the respective battery models may include determining normal distribution probabilities based on the difference values between the voltage values of the battery models estimated based on the estimated resistance parameters of the respective battery models and the actually measured voltage value, and determining the weights for the respective battery models based on the determined normal distribution probabilities.

In yet another exemplary embodiment of the present disclosure, determining the weights for the respective battery models may include determining the weights for the respective battery models by dividing probabilities that the actually measured voltage value is included in the respective battery models by a sum of the probabilities that the actually measured voltage value is included in the respective battery models, respectively.

In still yet another exemplary embodiment of the present disclosure, determining the fused OCV may include determining the fused OCV by applying the weights for the respective battery models to the probabilities that the actually measured voltage value is included in the respective battery models.

In a further exemplary embodiment of the present disclosure, determining the fused OCV may further include determining the fused OCV as a sum of values obtained by applying the weights for the respective battery models to model OCVs determined from the respective battery models.

In another further exemplary embodiment of the present disclosure, the method may further include converting the fused OCV into a matrix type to be applied to a Kalman filter, and estimating the SOC value of the battery through the Kalman filter.

Various aspects of the present disclosure are directed to providing an apparatus for estimating a state of charge (SOC) value of a battery, including a measurer configured for measuring a voltage and a current of the battery, and a battery management system configured for estimating OCVs of respective battery models based on a measured initial voltage and a measured initial current of the battery, and to estimate the SOC value of the battery based on the estimated OCVs, wherein the battery management system includes a model OCV processor configured for determining OCV probabilities of the respective battery models based on the measured voltage and the measured current, and an estimation processor configured for estimating the SOC value of the battery based on the determined OCV probabilities of the respective battery models.

In an exemplary embodiment of the present disclosure, the model OCV processor may estimate resistance parameters of the respective battery models based on the voltage and the current measured by the measurer, and may convert the estimated resistance parameters by comparing an actually measured voltage value with voltage values estimated through the estimated resistance parameters.

In another exemplary embodiment of the present disclosure, the model OCV processor is configured for determining difference values between the voltage values estimated through the estimated resistance parameters and the actually measured voltage value, may be configured for determining probabilities that the battery corresponds to the respective battery models based on normal distribution probabilities determined based on the determined difference values, and may be configured for determining a fused OCV by applying weights for the respective battery models to the determined probabilities that the battery corresponds to the respective battery models based on determined model OCV information of the respective battery models.

In yet another exemplary embodiment of the present disclosure, the model OCV processor is configured for determining the weights for the respective battery models by dividing probabilities that the actually measured voltage value is included in the respective battery models by a sum of the probabilities that the actually measured voltage value is included in the respective battery models, respectively.

In yet another exemplary embodiment of the present disclosure, the model OCV processor is configured for determining the fused OCV by applying the weights for the respective battery models to model OCVs determined from the respective battery models in response to the measured voltage value.

In still yet another exemplary embodiment of the present disclosure, the model OCV processor is configured for determining the fused OCV as a sum of values obtained by applying the determined weights for the respective battery models to model OCVs determined from the respective battery models.

In a further exemplary embodiment of the present disclosure, the estimation processor may estimate the SOC value of the battery by applying the fused OCV to a Kalman filter.

Other aspects and exemplary embodiments of the present disclosure are discussed infra.

The above and other features of the present disclosure are discussed infra.

The methods and apparatuses of the present disclosure have other features and advantages which will be apparent from or are set forth in more detail in the accompanying drawings, which are incorporated herein, and the following Detailed Description, which together serve to explain certain principles of the present disclosure.

### BRIEF DESCRIPTION OF THE DRAWINGS

FIG. 1 is a block diagram of the configuration of an apparatus for estimating an SOC value of a battery according to an exemplary embodiment of the present disclosure;

FIG. 2 is a circuit diagram showing an equivalent circuit model forming one battery model according to an exemplary embodiment of the present disclosure;

FIG. 3 is a flowchart representing a method of estimating an SOC value of a battery according to an exemplary embodiment of the present disclosure;

FIG. 4 is a flowchart representing a method of estimating an OCV of the battery according to an exemplary embodiment of the present disclosure;

FIG. 5A is a graph representing determined OCVs of respective battery models according to an exemplary embodiment of the present disclosure; and

FIG. 5B is a graph comparatively representing a fused OCV determined based on the respective battery models and an actually measured OCV of the battery according to various exemplary embodiments of the present disclosure.

It should be understood that the appended drawings are not necessarily to scale, presenting a somewhat simplified representation of various exemplary features illustrative of the basic principles of the present disclosure. The specific design features of the present disclosure as included herein, including, for example, specific dimensions, orientations, locations, and shapes, will be determined in part by the particular intended application and use environment.

In the figures, reference numbers refer to the same or equivalent parts of the present disclosure throughout the several figures of the drawing.

### DETAILED DESCRIPTION

Reference will now be made in detail to various embodiments of the present disclosure(s), examples of which are illustrated in the accompanying drawings and described below. While the present disclosure(s) will be described in conjunction with exemplary embodiments of the present disclosure, it will be understood that the present description is not intended to limit the present disclosure(s) to those exemplary embodiments of the present disclosure. On the other hand, the present disclosure(s) is/are intended to cover not only the exemplary embodiments of the present disclosure, but also various alternatives, modifications, equivalents and other embodiments, which may be included within the spirit and scope of the present disclosure as defined by the appended claims.

Hereinafter, reference will be made in detail to various embodiments of the present disclosure, examples of which are illustrated in the accompanying drawings and described below. The present disclosure is not limited to the following embodiments, and the exemplary embodiments of the present disclosure may be implemented in various different forms. The exemplary embodiments are provided to make the description of the present disclosure thorough and to fully convey the scope of the present disclosure to those skilled in the art.

Furthermore, in the following description of the embodiments, it will be understood that the suffixes “part”, “unit”, “module”, etc. Indicate units for processing at least one function or operation, and may be implemented as software, hardware, or a combination of software and hardware.

The terminology used herein is for describing various exemplary embodiments only and is not intended to be limiting. As used herein, singular forms may be intended to include plural forms as well, unless the context clearly indicates otherwise.

Furthermore, various embodiments of the present disclosure may be implemented as software (for example, programs) including commands stored in machine-readable storage media which are readable by machines (for example, computers). The machines are apparatuses which are configured for calling stored commands from storage media and being operated depending on the called commands, and may include electronic apparatuses (for example, servers) according to the disclosed exemplary embodiments of the present disclosure. The commands may include code generated or executed by compliers or interpreters. The machine-readable storage media may be provided in the form of a non-transitory storage media. Here, the term “non-transitory” indicates that storage media do not include signals and are tangible, and does not discriminate between semi-permanent storage and temporary storage of data in the storage media.

A battery management system (BMS) 300 may be an electronic control unit (ECU) belonging to an ECU level, i.e., an apparatus which is configured to control a plurality of electronic devices used in a vehicle in an integrated way. For example, the BMS 300 may control all of processors belonging to a processor level and controllers belonging to a controller level. The BMS 300 may receive detecting data from the processors, may be configured to generate control commands configured to control the controllers to match a situation, and may transmit the control commands to the controllers. However, although the BMS 300 is described as belonging to the ECU which is a higher level than the processor level in the specification for convenience of explanation, one of the processors belonging to the processor level is configured as an ECU, and two processors may be combined to serve as an ECU.

Furthermore, according to various exemplary embodiments of the present disclosure, methods according to the various embodiments included in the specification may be provided to be included in a computer program product. The computer program product may be traded as a product between a seller and a buyer. The computer program product may be provided in the form of a machine-readable storage medium (for example, a compact disc read only memory (CD-ROM)), or may be distributed online through an application store (for example, the Play Store). In case of online distribution, at least a part of the computer program product may be at least temporarily stored in a storage medium, such as the memory of a server of a manufacturer, a server of the application store, or a relay server, or may be temporarily generated.

Hereinafter, reference will be made in detail to the exemplary embodiments of the present disclosure, examples of which are illustrated in the accompanying drawings and described below. Wherever possible, the same reference numbers will be used throughout the drawings to refer to the same or like parts, and a redundant description thereof will be omitted.

Various embodiments of the present disclosure relates to a method and apparatus for estimating an SOC value of a battery 200 in which probabilities that the battery 200 corresponds to a plurality of battery models through a current measured voltage of the battery 200 based on battery model information are determined, a fused OCV is determined based on the determined probabilities, and the SOC value of the battery 200 is estimated depending on the determined fused OCV.

Furthermore, the BMS 300 according to an exemplary embodiment of the present disclosure may store data of at least one battery model, and may output an open-circuit voltage (OCV) corresponding to the measured voltage based on the corresponding data. Furthermore, the OCV (i.e., the fused OCV) output from the BMS 300 may include characteristics which substantially correspond to those of the battery models stored in the BMS 300, or may include the characteristics of battery models not stored in the BMS 300. That is, various aspects of the present disclosure are directed to providing the method and apparatus for estimating the SOC value of the battery 200 in which the OCVs of the battery models are determined through the current measured voltage of the battery 200 and characteristic data of the battery models stored in the BMS 300 corresponding to battery models applied to various vehicle kinds, and the SOC value of the battery 200 is estimated using a fused OCV of the battery models.

Hereinafter, the meanings of main terms used in an exemplary embodiment of the present disclosure will be described in brief.

An open-circuit voltage (OCV) means a voltage between two electrodes, i.e., a cathode and an anode, of a battery in the thermal equilibrium state in which current is not discharged to the outside thereof, when no load is applied to the battery, and the maximum value of the OCV theoretically equals the value of the electromotive force of the battery.

An estimated voltage value means a voltage value predicted depending on a battery model applied to a battery terminal through an estimated parameter.

Furthermore, a measured voltage value and current value mean an actual voltage value and current value measured at the battery terminal.

The battery 200 means an electrical energy storage apparatus including one cell or a cell group, and here, the cell means a device configured to store chemical energy which may be converted into electrical energy.

The state of charge (SOC) value of the battery 200 means the current level of charge of the battery 200, and is equivalent to a fuel gauge. The units of the SOC are percentage points. The SOC value of 0% indicates the empty state of the battery 200, and the SOC value of 100% indicates the fully charged state of the battery 200. The SOC is mainly used to indicate the current state of charge of the battery 200 in use.

Furthermore, the battery management system (BMS) 300 is an electronic system which manages the rechargeable battery 200, battery cells, or battery packs, and the BMS 300 is configured to perform management tasks, such as protection of the battery 200 so that the battery 200 is not operated outside a safe operation area, monitoring of the state of the battery 200, determination of secondary data, reporting of the data, control of the environments of the battery 200, and authentication and/or balancing of the battery 200, but are not limited to these tasks.

Furthermore, estimation of the SOC value of the battery 200 through the OCV according to an exemplary embodiment of the present disclosure is performed through an SOC estimation algorithm using the Kalman filter in which the SOC value of the battery 200 is estimated through active correction by electrically modeling the battery 200 and comparing an actual output value of the battery 200 with the theoretical output value of the battery model. In the SOC estimation algorithm using the Kalman filter, input values may include voltage, current, temperature, etc., and the output value is the SOC value of the battery 200. The SOC estimation algorithm using the Kalman filter is widely known through numerous references which were conventionally well-known, and a detailed description of a process of estimating the SOC in the SOC estimation algorithm using the Kalman filter will thus be omitted.

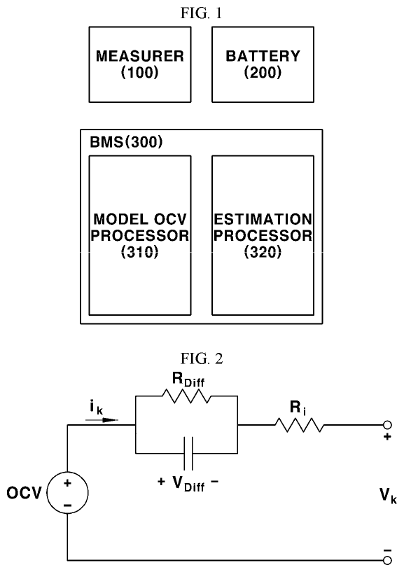

FIG. 1 is a block diagram of the configuration of an apparatus for estimating the SOC value of the battery 200 according to various exemplary embodiments of the present disclosure.

The apparatus according to an exemplary embodiment of the present disclosure includes the battery 200, and a measurer 100 configured for measuring an actual voltage value and an actual current value from a terminal of the battery 200. That is, the measurer 100 may measure an open-circuit voltage (OCV) of the battery 200 and a voltage and a current applied to the terminal of the battery 200, and the actually measured voltage and current data of the battery 200 is received by the BMS 300.

The detailed model of the battery 200 is not specified, and the battery 200 is configured so that the OCV output of the corresponding battery 200 is estimated using battery model data stored in the BMS 300. That is, the battery 200 according to an exemplary embodiment of the present disclosure may be mounted in the state in which a battery model applied thereto is not specified, the OCV of the battery 200 may be estimated depending on the respective battery models stored in the BMS 300, and the SOC value of the battery 200 may be estimated based on the estimated OCV.

The BMS 300 may include a model OCV processor 310 and an estimation processor 320. The BMS 300 may include data about an OCV of at least one battery model and an SOC estimated depending on the OCV. Therefore, the model OCV processor 310 may be configured for determining a fused OCV of the battery 200, which is subject to measurement, using the stored data of the respective battery models, and may estimate the SOC value of the battery 20 based on the fused OCV.

Furthermore, the BMS 300 may include equivalent circuit information of the respective battery models, and may include resistance parameters estimated based on the equivalent circuit information and voltage values applied to the terminals of the battery models and estimated based on the estimated resistance parameters. In various exemplary embodiments of the present disclosure, the estimated resistance parameters may mean resistances estimated through predefined OCV information. Therefore, the model OCV processor 310 is configured for estimating resistance parameters of the respective battery models based on the initial voltage and initial current initially measured by the measurer 100, and to convert the estimated resistance parameters by comparing the estimated resistance parameters with an actually measured voltage value.

That is, estimation of the resistance parameters by the model OCV processor 310 may be performed through equivalent circuit models of the respective battery models stored in the BMS 300, and difference values (error values) are determined by comparing the actually measured voltage value with the voltage values of the respective battery models estimated based on the estimated resistance parameters. In the present way, the error values stored in the model OCV processor 310 may be determined based on differences between the actually measured voltage value and the voltage values estimated based on the estimated resistance parameters stored in the BMS 300.

Furthermore, the model OCV processor 310 may output the converted resistance parameters by applying weights to the determined error values and determining error covariances, and may be configured for determining model OCVs output from the corresponding battery models by applying the converted resistance parameters.

Moreover, the model OCV processor 310 may output probability density functions of the respective battery models by converting the estimated voltage values of the respective battery models into normal distribution probabilities based on the error values of the estimated voltage values of the respective battery models and the actually measured voltage value. The model OCV processor 310 may be configured for determining a probability that a corresponding battery model will be selected in response to the current measured voltage based on the output probability density function.

Furthermore, the model OCV processor 310 is configured for determining a weight in determination of the probability that the corresponding battery model will be selected, and a weights for each of the battery models is determined by dividing a probability that the measured voltage value is included in the corresponding battery model by the sum of probabilities that the actually measured voltage value is included in the respective battery models. The sum of all weights for the respective battery models is 1.

Furthermore, the model OCV processor 310 is configured to output the fused OCV by multiplying the model OCVs output from the respective battery models by the determined weights, respectively.

The estimation processor 320 according to an exemplary embodiment of the present disclosure is configured to derive an SOC-OCV model by applying the output value of the fused OCV to the Kalman filter, and to estimate the SOC value of the battery 200 in response to the fused OCV.

Furthermore, the estimation processor 320 is configured to convert the fused OCV into a matrix type to be applied to the Kalman filter, and to estimate the SOC value of the battery 200 based on the fused OCV converted into the matrix type.

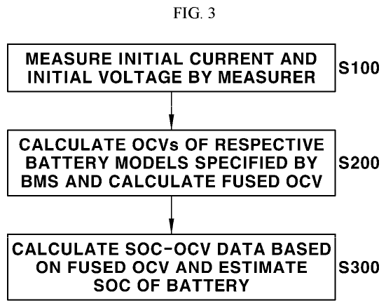

FIG. 2 shows the configuration of a resistance parameter equivalent circuit of one of the battery modules stored in the BMS 300 according to various exemplary embodiments of the present disclosure.

As shown in the present figure, a battery equivalent circuit is data of a battery model stored in the BMS 300, and the OCV of the battery 200 is determined based on the initial current and initial voltage of the battery 200 measured by the measurer 100.

That is, the resistance parameters may be determined by Equation 1 below.

$${V}_{qk} = - {a}_{1} {V}_{qk - 1} + {b}_{0} {I}_{k} - {b}_{1} {I}_{k - 1} \qquad [ Equation 1 ]$$

$${V}_{qk} = {[ {V}_{qk - 1} , {I}_{k} , {I}_{k - 1} ] [ - {a}_{1} , {b}_{0} , {b}_{1} ]}^{T} = {φ}_{k} {θ}_{k}^{T}$$

Equation 1 above represents voltage relations depending on a K-degree, and V_{q} indicates a difference between the actually measured voltage value Vₜ and an OCV determined depending on the equivalent circuit model of the corresponding battery model. Furthermore, as factors of Equation 1, V_{qk} indicates an overpotential, i.e., a difference obtained by subtracting a predefined OCV from the actually measured voltage (V_{q}=Vₜ−OCV), coefficients a₁, b₀, and b₁ indicate parameters estimated by the recursive least square method, Iₖ indicates a measured current, φₖ indicates an input vector, and θ indicates a parameter vector.

Furthermore, the resistance parameters a₁, b₀, and b₁ may be determined as below depending on the corresponding equivalent circuit model.

$${a}_{1} = {t}_{s} / ( {C}_{diff} {R}_{diff} ) - 1$$

$${b}_{0} = {R}_{i}$$

$${b}_{1} = - {R}_{i} + {T}_{s} / {C}_{diff} + ( {T}_{s} {R}_{i} ) / ( {C}_{diff} {R}_{i} )$$

As described above, the resistance parameters may be determined based on the equivalent circuit data of the battery model stored in the BMS 300.

That is, when V_{q}=Vₜ−OCV is applied to Equation 1 above, V_{t,k} may be determined by Equation 2 below.

$${V}_{t , k} = {[ {I}_{k} ; {I}_{k - 1} ; {V}_{q , k - 1} , 1 ] [ {b}_{o , k} ; {b}_{1 , k} ; {a}_{o , k} ; {OCV}_{k} ]}^{T} = {φ}_{k} {θ}_{k}^{T} \qquad [ Equation 2 ]$$

V_{t,k} determined by Equation 2 represent the resistance parameters determined based on the equivalent circuit data, and the model OCV processor 310 is configured for determining an error value through a difference between actually measured V_{q,k} and φₖθₖ₋ₗ^{T}, and is configured for determining converted resistance parameters by determining a weight and an error covariance.

Model OCV values determined from the respective battery models are estimated through the converted parameters which are determined as above.

That is, the model OCV processor 310 according to an exemplary embodiment of the present disclosure is configured for determining the estimated model OCVs of the respective battery models through the converted parameters by comparing the actually measured voltage value with the voltage values estimated based on the equivalent circuits stored in the BMS 300.

Furthermore, the model OCV processor 310 is configured for determining probabilities of the respective battery models based on the above-determined error values of the respective battery models.

That is, the model OCV processor 310 is configured to perform a process of determining probability density functions using the determined errors of the respective battery models and determining probabilities through error covariances based on Equation 3 below.

$${res}_{i} ( k ) = {V}_{t} ( k ) - {\hat{V}}_{t , i} ( k ) \qquad [ Equation 3 ]$$

$$f ( {V}_{t} ( k ) \vert {p}_{i} ) = \frac{1}{{( 2 π )}^{q / 2} {p}_{i}^{1 / 2} ( k )} \times exp ( {res}_{i}^{T} ( k ) {P}_{i}^{- 1} ( k ) {res}_{i} ( k ) / 2 )$$

$$Pr ( {p}_{j} \vert {V}_{t} ( k ) ) = \frac{f ( {V}_{t} ( k ) \vert {p}_{i} ) Pr ( {p}_{j} )}{{\sum }_{i = 1}^{N} f ( {V}_{t} ( k ) \vert {p}_{i} ) Pr ( {p}_{i} )}$$

$$∴ Pr ( {p}_{i} ) = \frac{1}{N} ( prior probability )$$

$$Pr ( {p}_{i} \vert {V}_{t} ( k - 1 ) ) = \frac{Pr ( {V}_{t} ( k - 1 ) \vert {p}_{i} ) Pr ( pi )}{Pr ( {V}_{t} ( k - 1 ) \vert {p}_{i} )}$$

$${ω}_{i} = Pr ( {p}_{j} \vert {V}_{t} ( k ) ) = \frac{f ( {V}_{t} ( k ) \vert {p}_{i} ) Pr ( {p}_{i} \vert {V}_{t} ( k - 1 ) )}{{\sum }_{i = 1}^{N} f ( {V}_{t} ( k ) \vert {p}_{i} ) Pr ( {p}_{i} \vert {V}_{t} ( k - 1 ) )}$$

Here, q is the number of measured values, and in various exemplary embodiments of the present disclosure, the probability of each battery model is determined based on the voltage value, and thus, q is set to 1.

Furthermore, as factors of Equation 3, \hat{V}_{t,i}(k) indicates an estimated voltage value depending on the i^{th} battery model, i indicates the number of the battery models, Pi is an error covariance of recursive least squares of each battery model, ƒ(Vₜ(k)|pᵢ) indicates a probability density function, Pr(pⱼ|Vₜ(k)) indicates a conditional probability (i.e., a conditional probability of an event Pⱼ when the measured voltage Vₜ is given), pⱼ indicates a variance of the battery models provided in the number of J, Vₜ(k) indicates a measured voltage, and Pr(pi) indicates a prior probability that one battery model will be selected compared to the number of the battery models. In various exemplary embodiments of the present disclosure, the prior probability is set to 1/N (the number of the battery models).

Furthermore, the weight Wi for a probability that one battery model will be selected in response to the measured voltage value of the battery 200 at a point in time K may be determined by dividing the probability of the corresponding battery model by the sum of the probabilities of all the battery models, as described above. That is, the sum of the weights Wi of the respective battery models becomes 1.

That is, the fused OCV is determined as the sum of values obtained by multiplying the weights Wi of the respective battery models by the determined OCVs of the corresponding battery models by Equation 4 below.

$$O \hat{C} {V}_{fused} = {ω}_{NCM} {\hat{Z}}_{NCM} + {ω}_{LMO} {\hat{Z}}_{LMO} + {ω}_{LCA} {\hat{Z}}_{LCA} \qquad [ Equation 4 ]$$

In Equation 4 above, \hat{Z} indicates the determined model OCV of each of the battery models.

Furthermore, the estimation processor 320 derives the SOC-OCV model by converting the fused SOC into a matrix type to be applied to the Kalman filter. Therefore, the estimation processor 320 estimates the SOC value of the battery 200 based on the fused OCV.

In the present way, the BMS 300 according to an exemplary embodiment of the present disclosure is configured for determining probabilities that the battery 200 corresponds to the respective battery models depending on a measured voltage value based on the battery model data information stored in the BMS 300, and is configured for determining weights based on the determined probabilities.

Furthermore, various aspects of the present disclosure are directed to providing technology for determining a fused OCV by applying the determined weights to OCVs determined from the respective battery models, and estimating the SOC value of the battery based on the fused OCV.

Here, the fused OCV may track the respective battery models stored in the BMS 300, or may track a separate battery model which is not stored in the BMS 300. Therefore, the present disclosure may estimate an OCV value applied from an unconfirmed battery model based on information related to multiple battery models.

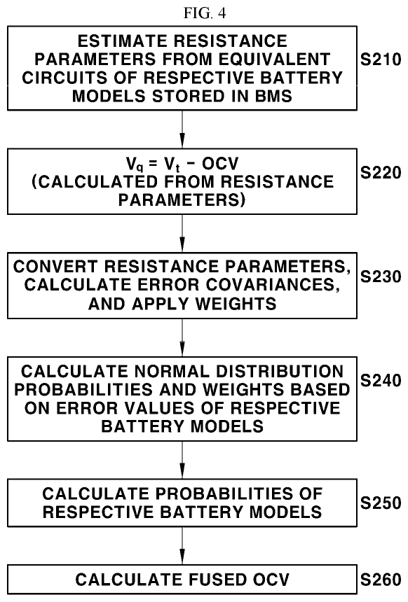

FIG. 3 is a flowchart representing a method of estimating the SOC value of the battery 200 through the BMS 300 including a plurality of battery models, according to various exemplary embodiments of the present disclosure.

In the method, the fused OCV of the battery 200, which is mounted currently, is estimated based on the battery model information stored in the BMS 300, and the SOC value of the battery 200 is estimated by applying the fused OCV data to the Kalman filter.

For the present purpose, first, the initial voltage and initial current of the battery 200 are measured (S100). The resistance parameters of the battery models stored in the BMS 300 are estimated based on the measured initial voltage and the measured initial current. Thereafter, error values are determined by comparing an actually measured voltage value with voltage values of the battery models estimated using the estimated resistance parameters, and probabilities that the mounted battery 200 tracks the respective stored battery models based on the determined error values. Weights applied to the respective battery models are output based on the determined probabilities, and the fused OCV is output by applying OCVs determined from the respective battery models to the output weights (S200).

The fused OCV is applied to the Kalman filter, and SOC-OCV data is output by updating state variables and error covariances through Kalman gain determination. The SOC corresponding to the fused OCV may be estimated based on the SOC-OCV data, and therefore, the SOC value of the battery 200 mounted currently may be determined without performance information and data of the mounted battery 200. Furthermore, the BMS 300 converts the fused OCV information into a matrix type to be applied to the Kalman filter, and applies the converted OCV information to the Kalman filter (S300).

That is, various aspects of the present disclosure are directed to providing technology that estimates the fused OCV and estimates the SOC value of the battery 20 based on the tracked fused OCV through the BMS 300.

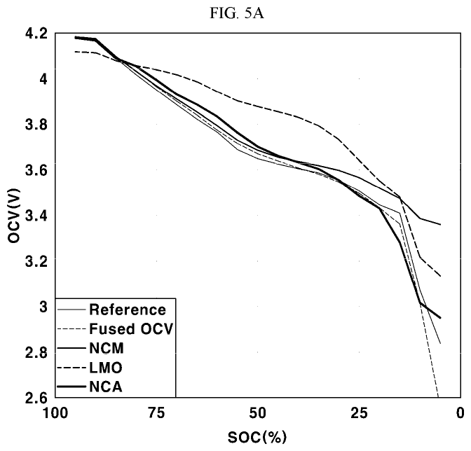

FIG. 4 is a flowchart representing a method of estimating the fused OCV of the battery 200 to estimate the SOC value of the battery 200 according to various exemplary embodiments of the present disclosure.

The BMS 300 measures the initial voltage and initial current of the battery 200, and estimates the resistance parameters of the respective battery models based on the measured initial voltage and the measured initial current (S210). Furthermore, the BMS 300 converts the estimated resistance parameters by comparing the actually measured voltage value with OCVs determined through the estimated resistance parameters (S220).

In case of conversion of the resistance parameters, the model OCV processor 310 is configured to perform conversion of the estimated resistance parameters based on difference values between the voltage values of the respective battery models estimated through the estimated resistance parameters of the respective battery models and the actually measured voltage value (S230). Furthermore, error covariances are determined based on the difference values (error values), and weights are applied (S230). Conversion of the resistance parameters is performed by determining the error covariances based on the error values and applying the weights, as described above (S230).

Thereafter, the model OCVs of the respective battery models are determined based on the converted resistance parameters, and are stored in the BMS 300.

The model OCV processor 310 is configured for determining probabilities that the mounted battery 200 corresponds to the respective battery models through the actually measured voltage value based on the determined error values. That is, the model OCV processor 310 is configured for determining normal distribution probabilities based on the difference values (error values) between the voltage values of the respective battery models estimated through the estimated resistance parameters of the respective battery models and the actually measured voltage value (S240), and is configured for determining the weights for the respective battery models based on the determined normal distribution probabilities (S250).

In determination of the weights for the respective battery models, the weights for the respective battery models are determined by dividing probabilities that the actually measured voltage value is included in the respective battery models by the sum of the probabilities that the actually measured voltage value is included in the respective battery models, respectively (S250).

Thereafter, the model OCV processor 310 is configured for determining the fused OCV by applying the weights to the probabilities that the measured voltage value corresponds to the respective battery models (S260). The model OCV processor 310 is configured for determining the fused OCV as the sum of values obtained by applying the weights to the determined model OCVs of the respective battery models.

The estimation processor 320 estimates the OCV of the battery by applying the fused OCV determined by the model OCV processor 310 to the Kalman filter.

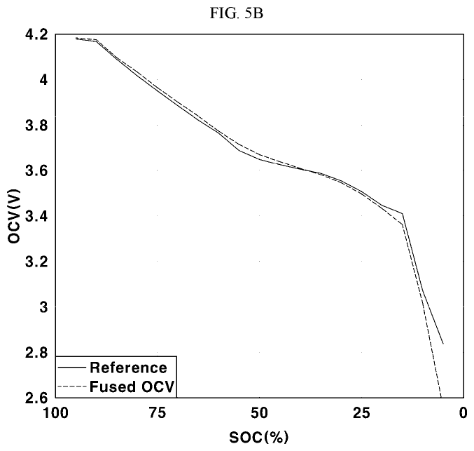

FIG. 5A and FIG. 5B represent information related to three battery models stored in the BMS 300, a fused OCV therethrough, and voltage information applied as a reference, according to various exemplary embodiments of the present disclosure.

As shown in these figures, information stored in the BMS 300 according to an exemplary embodiment of the present disclosure includes SOC-OCV data of the three battery models. Furthermore, the three battery models stored in the BMS 300 may include different SOC-OCV data.

Here, the reference indicates the SOC-OCV data of the battery 200, which is currently mounted as a driving unit, and the results shown in FIG. 5B may be derived through the fused OCV of the respective battery models based on the reference data.

That is, in FIG. 5A, the respective battery models stored in the BMS 300 exhibit different SOCs in a region in which the OCV is equal to or less than 3.6 V, compared to the information of the battery 200 applied as the reference.

Therefore, the BMS 300 according to various exemplary embodiments of the present disclosure is configured for determining the fused OCV of the three battery models, and the determined fused OCV derives SOC-OCV estimation data which is substantially the same as the reference, as shown in FIG. 5B.

In the present way, in an exemplary embodiment of the present disclosure, the fused OCV of the mounted battery 200 which is not stored in the BMS 300 may be estimated, and the fused OCV provides estimated values which are substantially the same as the SOC-COV data of the mounted battery 200.

Furthermore, because the SOC value of the battery 200 may be estimated through the fused OCV, various aspects of the present disclosure are directed to providing technology which may estimate the OCV of the battery 200, which is not specified, and may estimate the SOC value of the battery 200 through tracking of the SOC-COV data obtained using the Kalman filter based on the estimated OCV.

As is apparent from the above description, various aspects of the present disclosure are directed to providing the following effects through the above-described configuration and connection and usage relations.

In an exemplary embodiment of the present disclosure, an OCV of a battery, which is actually mounted currently as a driving unit, may be estimated, being configured for optimizing a battery characteristic test.

Furthermore, in an exemplary embodiment of the present disclosure, a fused OCV may be determined based on stored battery model information as the OCB of the mounted battery, and an SOC value of the battery may be estimated using the fused OCV, being configured for providing an efficient method for battery quality verification.

Furthermore, the battery may be operated under optimum conditions based on the estimated SOC value.

For convenience in explanation and accurate definition in the appended claims, the terms “upper”, “lower”, “inner”, “outer”, “up”, “down”, “upwards”, “downwards”, “front”, “rear”, “back”, “inside”, “outside”, “inwardly”, “outwardly”, “interior”, “exterior”, “internal”, “external”, “forwards”, and “backwards” are used to describe features of the exemplary embodiments with reference to the positions of such features as displayed in the figures. It will be further understood that the term “connect” or its derivatives refer both to direct and indirect connection.

The term “and/or” may include a combination of a plurality of related listed items or any of a plurality of related listed items. For example, “A and/or B” includes all three cases such as “A”, “B”, and “A and B”.

The foregoing descriptions of specific exemplary embodiments of the present disclosure have been presented for purposes of illustration and description. They are not intended to be exhaustive or to limit the present disclosure to the precise forms disclosed, and obviously many modifications and variations are possible in light of the above teachings. The exemplary embodiments were chosen and described in order to explain certain principles of the invention and their practical application, to enable others skilled in the art to make and utilize various exemplary embodiments of the present disclosure, as well as various alternatives and modifications thereof. It is intended that the scope of the present disclosure be defined by the Claims appended hereto and their equivalents.

What is claimed is:

1. A method of estimating a state of charge (SOC) value of a battery, the method comprising:
measuring an initial voltage and an initial current of the battery;
estimating, by a battery management system, resistance parameters of respective battery models based on the measured initial voltage and the measured initial current;
converting, by the battery management system, the estimated resistance parameters by comparing an actually measured voltage value with open-circuit voltage (OCV)s determined through the estimated resistance parameters;
determining, by the battery management system, probabilities that the battery corresponds to the respective battery models based on difference values between voltage values of the battery models estimated based on the estimated resistance parameters of the respective battery models and the actually measured voltage value;
determining, by the battery management system, a fused OCV by applying weights for the respective battery models to the determined probabilities that the battery corresponds to the respective battery models based on model OCV information of the respective battery models determined based on the converted resistance parameters; and
estimating, by the battery management system, the SOC value of the battery based on the fused OCV.

2. The method of claim 1, wherein the converting of the estimated resistance parameters includes:
converting the estimated resistance parameters based on difference values between the OCVs determined through the estimated resistance parameters of the respective battery models and the actually measured voltage value; and
determining OCVs of the respective battery models based on the converted resistance parameters.

3. The method of claim 2, wherein the converting of the estimated resistance parameters based on the difference values between the OCVs determined through the estimated resistance parameters of the respective battery models and the actually measured voltage value includes:
converting the estimated resistance parameters by determining error covariances and applying weights to the difference values between the OCVs through the estimated resistance parameters of the respective battery models determined and the actually measured voltage value.

4. The method of claim 1, wherein the determining of the probabilities that the battery corresponds to the respective battery models includes:
determining normal distribution probabilities based on the difference values between the voltage values of the battery models estimated based on the estimated resistance parameters of the respective battery models and the actually measured voltage value; and
determining the weights for the respective battery models based on the determined normal distribution probabilities.

5. The method of claim 4, wherein the determining of the weights for the respective battery models includes:
determining the weights for the respective battery models by dividing probabilities that the actually measured voltage value is included in the respective battery models by a sum of the probabilities that the actually measured voltage value is included in the respective battery models, respectively.

6. The method of claim 5, wherein the determining of the fused OCV includes:
determining the fused OCV by applying the weights for the respective battery models to the probabilities that the actually measured voltage value is included in the respective battery models.

7. The method of claim 6, wherein the determining of the fused OCV further includes:
determining the fused OCV as a sum of values obtained by applying the weights for the respective battery models to model OCVs determined from the respective battery models.

8. The method of claim 6, further including:
converting, by the battery management system, the fused OCV into a matrix type to be applied to a Kalman filter; and
estimating the SOC value of the battery through the Kalman filter.

9. An apparatus for estimating a state of charge (SOC) value of a battery, the apparatus comprising:
a measurer configured for measuring a voltage and a current of the battery; and
a battery management system configured for estimating open-circuit voltage (OCV)s of respective battery models based on a measured initial voltage and a measured initial current of the battery, and for estimating the SOC value of the battery based on the estimated OCVs,
wherein the battery management system includes:
a model OCV processor configured for determining OCV probabilities of the respective battery models based on the measured voltage and the measured current; and
an estimation processor configured for estimating the SOC value of the battery based on the determined OCV probabilities of the respective battery models.

10. The apparatus of claim 9, wherein the model OCV processor is configured for estimating resistance parameters of the respective battery models based on the voltage and the current measured by the measurer, and for converting the estimated resistance parameters by comparing an actually measured voltage value with voltage values estimated through the estimated resistance parameters.

11. The apparatus of claim 10, wherein in converting the estimated resistance parameters, the model OCV processor is further configured for:
converting the estimated resistance parameters based on difference values between the OCVs determined through the estimated resistance parameters of the respective battery models and the actually measured voltage value; and
determining OCVs of the respective battery models based on the converted resistance parameters.

12. The apparatus of claim 11, wherein in converting the estimated resistance parameters based on the difference values between the OCVs determined through the estimated resistance parameters of the respective battery models and the actually measured voltage value, the model OCV processor is further configured for:
converting the estimated resistance parameters by determining error covariances and applying weights to the difference values between the OCVs through the estimated resistance parameters of the respective battery models determined and the actually measured voltage value.

13. The apparatus of claim 10, wherein the model OCV processor is configured for determining difference values between the voltage values estimated through the estimated resistance parameters and the actually measured voltage value, is configured for determining probabilities that the battery corresponds to the respective battery models based on normal distribution probabilities determined based on the determined difference values, and is configured for determining a fused OCV by applying weights for the respective battery models to the determined probabilities that the battery corresponds to the respective battery models based on determined model OCV information of the respective battery models.

14. The apparatus of claim 13, wherein the model OCV processor is configured for determining the weights for the respective battery models by dividing probabilities that the actually measured voltage value is included in the respective battery models by a sum of the probabilities that the actually measured voltage value is included in the respective battery models, respectively.

15. The apparatus of claim 14, wherein the model OCV processor is configured for determining the fused OCV by applying the weights for the respective battery models to model OCVs determined from the respective battery models in response to the measured voltage.

16. The apparatus of claim 15, wherein the model OCV processor is configured for determining the fused OCV as a sum of values obtained by applying the determined weights for the respective battery models to model OCVs determined from the respective battery models.

17. The apparatus of claim 9, wherein the estimation processor is configured for estimating the SOC value of the battery by applying the fused OCV to a Kalman filter.
